(19) United States
(12) Patent Application Publication
(10) Pub. No.: US 2024/0305110 A1
(43) Pub. Date: Sep. 12, 2024

(54) Battery Cell Balancing Systems and Method

(71) Applicant: Enconnex LLC, Reno, NV (US)

(72) Inventors: Anthony Dela Cruz, Reno, NV (US); Benjamin Luke, Sparks, NV (US); OmegaJune Zareno, Reno, NV (US)

(21) Appl. No.: 18/335,239

(22) Filed: Jun. 15, 2023

Related U.S. Application Data
(60) Provisional application No. 63/489,672, filed on Mar. 10, 2023.

(51) Int. Cl. H02J 7/00; G01R 31/364; G01R 31/3835

(52) U.S. Cl. CPC H02J 7/0016; G01R 31/364; G01R 31/3835; H02J 7/0047; H02J 7/0063; H02J 7/007182

(57) ABSTRACT

A battery management system implements a cell balancing method. In the method, the voltages of a set of battery cells are measured, typically at a regular interval. A controller, or another element of the battery management system, calculates statistics describing the measured voltages. These statistics typically include a measure of central tendency and a measure of variability. While the variability statistic is greater than a predefined threshold and each of the set of battery cell voltages is greater than a stop voltage, ones or groups of the set of battery cells are drained according to a predefined set of priority rules until the variability statistic is less than or equal to the predefined threshold or any one of the set of battery cells has a voltage less than or equal to a stop voltage. The stop voltage may be, or be derived from, the measure of central tendency.

### CROSS-REFERENCE TO RELATED APPLICATIONS

This application claims priority to, and the benefit of, U.S. Provisional Patent Application No. 63/489,672, filed Mar. 10, 2023. The contents of that application are incorporated by reference herein in their entirety.

### TECHNICAL FIELD

The invention relates to methods for monitoring and controlling multi-cell battery packs, and in particular, to methods for balancing the charge of cells in a battery pack.

### BACKGROUND

In industry and in consumer products, batteries are a fact of modern life. Among myriad uses, they provide primary power for consumer electronics and wireless devices, provide backup power for enterprise and server computing equipment, and provide energy storage for larger power systems, like solar power systems.

A single battery cell supplies a small amount of current at a low voltage. Thus, whenever higher voltages or larger currents are required, a number of cells are connected together, in series, in parallel, or in some combination of series and parallel, to create a battery pack. Depending on the voltage and current requirements, a battery pack may include any number of cells.

Because battery cells use controlled chemical reactions to store and discharge energy, every type of battery has a range of conditions under which it can be safely and reliably operated. These conditions may include a safe operating temperature range, as well as voltage and current limits during both charging and discharging operations. If the battery cell's limits are exceeded, the cell's performance may be permanently affected, its life may be shortened and, in serious cases, catastrophic failure can occur, resulting in fire or explosion.

Battery management systems are used to keep battery packs operating efficiently within their limits. These systems measure temperature, current, voltage, and other such parameters and can either directly control or indirectly influence the charging and discharging of the battery pack based on the measured parameters.

Another function commonly performed by battery management systems is cell balancing. In a multi-cell battery pack, each cell may charge differently, and at any given moment, each cell may be in a different state of charge. The output voltage of a battery cell is a function of its state charge, with less-charged cells having lower output voltages. In an unbalanced battery pack, the cells may have widely-varying output voltages. Because the power that can be delivered by a battery cell is a function of its voltage, and the power that can be delivered by a battery pack is often limited by the cell with the lowest voltage, a battery pack with unbalanced cells cannot deliver as much power as a comparable battery pack in which the cells are balanced, i.e., in which the cells all have the same, or about the same, voltage.

### BRIEF SUMMARY

Aspects of the invention relate to battery balancing methods, to battery management systems implementing these methods, and to devices using battery packs and battery management systems that implement these methods.

A battery balancing method according to one embodiment of the invention reads voltages of cells in a battery pack and calculates one or more statistics describing those voltages. The statistics would typically be measures of the central tendency of the cell voltages and the variability of the cell voltages but may be any other statistical measures capable of describing the state of charge of a number of the cells in the battery pack. The maximum and minimum cell voltages may also be noted.

The calculated statistics are compared with predefined thresholds to determine whether cell balancing is needed. For example, a measure of voltage variability, like the standard deviation of the measured cell voltages, may be compared with a predefined threshold to determine whether balancing is required. If cell balancing is required, cells are balanced by discharging power from them in a priority order determined by a predetermined set of rules. Cell balancing continues according to the priority order while the measure of variability is greater than the predetermined threshold and while all cells have voltages greater than a stop voltage. The stop voltage may be related to a measure of the central tendency of the battery cell voltages, and serves as an indication, e.g., that the voltage of at least one cell has fallen sufficiently such that cell balancing should stop. For example, cell balancing may continue while the standard deviation of the cell voltages is greater than the predetermined threshold and while no cell has a voltage less than or equal to the mean cell voltage. However, in some cases, the stop voltage may be a predefined voltage related to the normal operating voltage range of the battery cells, and may not be related to, or dependent on, the calculated statistics.

In some embodiments, voltage data may be gathered at a regular rate independent of the cell balancing method.

Other aspects, features, and advantages of the invention will be set forth in the description that follows.

### BRIEF DESCRIPTION OF THE DRAWING FIGURES

The invention will be described with respect to the following drawing figures, in which like numerals represent like features throughout the description, and in which:

FIG. 1 is a schematic diagram of a battery management system connected to a battery pack according to one embodiment of the invention; and

FIG. 2 is a flow diagram of a method for battery cell balancing according to one embodiment of the invention.

### DETAILED DESCRIPTION

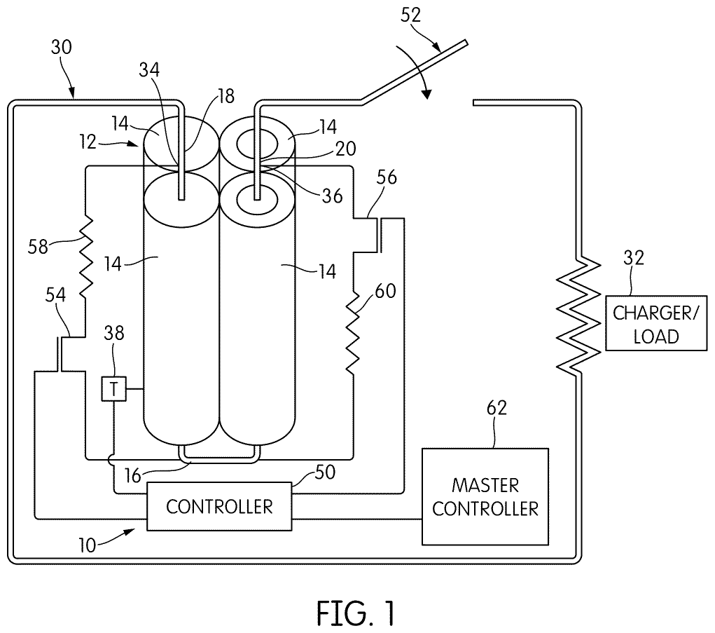

FIG. 1 is a schematic diagram of a battery management system, generally indicated at 10, according to one embodiment of the invention, shown connected to a battery pack 12.

The battery pack 12 may have any number of cells 14 in it, and these cells may be connected in series, in parallel, or in some combination of series and parallel, to provide more power than could be provided by any one cell 14 alone. In the illustrated embodiment, there are four cells 14 which will be assumed, for purposes of this description, to be connected such that pairs of two cells 14 are connected in parallel with one another, and both pairs of cells 14 are connected in series with one another. There is some internal connecting structure 16 provided within the battery pack 12 to create the appropriate connections between cells 14. For example, the individual cells 14 may be tack-welded or otherwise connected to metal bars, foils, or other types of connectors. The battery pack 12 also has positive and minus-return main bus bars 18, 20 with terminals that connect to the main power circuit, generally indicated at 30. The main power circuit 30 includes a charger and a load, indicated schematically in the aggregate in FIG. 1 at 32. The battery pack 12 thus supplies power to a load and receives power from a charger through the main power circuit.

The nature of the battery cells 14 themselves is not critical. They may have any chemistry or attributes. Lead-acid battery cells and lithium-ion battery cells are two common chemistries. The remainder of this description will assume that the battery cells 14 are lithium-ion battery cells, a characterization that encompasses several types of different lithium-based battery chemistries.

The overall purpose of the battery management system 10 is to monitor the battery pack 12 and to control the charging and discharging of the battery pack 12 to keep within safe and reasonable operating limits and to maximize the performance of the battery pack 12. The precise setpoints that are used within the battery management system 10 will depend on the chemistry of the battery cells 14 (e.g., lithium-ion or lead-acid), any other relevant attributes of the battery cells 14, as well as the power demand and environment.

More specifically, the electrical connecting structure 16 within the battery pack 12 allows for a number of taps or monitoring terminals 34, 36. The terminals 34, 36 are low-current terminals that allow for cell voltage and current monitoring, as well as cell-balancing operations. Typically, there would be one terminal 34, 36 per battery cell 14, so that all cells 14 can be monitored. However, if cells 14 are connected in parallel, there would typically be one monitoring terminal 34, 36 per set of cells 14 that are connected in parallel. Because the present example assumes two sets or pairs of battery cells 14 connected in parallel, there are two terminals 34, 36. In addition to voltage and current monitoring, a battery pack 12 is usually provided with at least one temperature sensor 38, which may be a thermistor, a thermocouple, or any other suitable device. In battery packs with many cells 14, temperature sensors 38 may be provided for every cell 14 or for groups of cells 14.

A controller 50 is coupled to the terminals 34, 36 and also receives input from the temperature sensor 38. These connections would typically be by way of wiring harnesses connected to the terminals 34, 36, although these components are omitted from the view of FIG. 1 for the sake of clarity in illustration. The controller 50 is the element responsible for controlling and directing the functions of the battery management system 10. Depending on the embodiment, the controller 50 may be a device such as a microcontroller, a microprocessor, an application-specific integrated circuit (ASIC), a field-programmable gate array (FPGA), or any other device that can perform the functions ascribed to it here.

Generally speaking, the controller 50 determines the state of charge and condition of the battery pack 12 and its cells 14 and takes action accordingly. More specifically, the controller 50 is coupled to, and controls, a number of switching and other elements. In the simplified schematic of FIG. 1, a switch 52 connects the battery pack 12 to the charger and load 32. One switch 52 is shown for case in illustration. In practice, there would typically be separate switching elements to connect the battery pack 12 to the load and to the charger. The switching element or elements 52 will typically be automatic but may be automatic or manual. That is, the controller 50 will usually determine the state of charge and condition of the battery pack 12 and its cells 14 and automatically connect the battery pack 12 to the charger or load as needed, e.g., by way of a transistor or set of transistors. In some cases, however, the controller 50 may establish a signal to alert an operator to manually actuate a switching element or elements 52. The controller 50 may also control additional elements, not shown in FIG. 1, to control the rate of charge and the rate of discharge. Any known elements and/or circuit topologies may be used to accomplish these functions.

As particularly relevant here, the controller 50 is also adapted to perform and/or direct cell balancing functions. In general, the terms “cell balancing” and “battery cell balancing” refer to methods that tend to equalize the state of charge and/or voltage of two or more cells in a battery pack 12. There are several ways in which this can be done. So-called “passive” cell balancing methods include selectively limiting the rate of charge of one or more cells, or selectively discharging one or more cells to achieve balance. Typically, balance is achieved when the voltage on all cells 14 within a battery pack 12 is the same, at least to within a predetermined threshold.

The controller 50 of FIG. 1 is configured and adapted to selectively drain or discharge individual cells 14 (or, in the case of cells 14 connected in parallel, individual groups of cells 14) in order to achieve cell balance. Specifically, as can be seen in FIG. 1, the controller 50 is coupled to switching elements 54, 56 that can discharge power from the terminals 34, 36 through resistors 58, 60. (The switching elements 54, 56 and resistors 58, 60 are shown as separate components in FIG. 1 for ease in description; in a typical installation, these would be components on a circuit board that are connected to the cells 14 through the terminals 34, 36 and wiring harnesses.)

The term “switching element,” as used here and above, is a broad term that refers to any element, or set of elements, that can be used to switch between one path, option, or state and another. The switching elements 54, 56 will almost always be automatic switching elements, like transistors or relays, although in some embodiments, the controller 50 may generate a signal directing a human operator to use a conventional, manual switch to change the state. In high-powered applications, the switching elements 54, 56 may be, e.g., an insulated gate bipolar transistor (IGBT) or another such device specifically engineered to handle large amounts of power. A single switching “element” may also comprise a group of elements, e.g., a transistor directly addressed and controlled by the controller 50 that, in turn, actuates switching elements with higher power tolerance to perform the desired function.

Each controller 50 typically has the ability to monitor and manage a certain number of cells 14. The nature and type of controller 50 would usually be chosen so that it has the capability to monitor and manage the number of cells 14 (or cells 14 connected in parallel) that are in the battery pack 12. However, if there are a particularly large number of cells 14 in a battery pack 12, or if there are multiple battery packs 12, there may be multiple controllers 50, each with responsibility for particular cells 14. In particularly large installations, there may be multiple battery management system printed circuit boards, each connected and dedicated to a certain number of battery cells 14 or battery packs 12.

In cases where there are a particularly large number of cells 14, where a single controller 50 has insufficient capacity to store and execute all of the necessary instructions or to perform all of the necessary tasks, or where there are multiple controllers 50, the functions of the battery management system 10 may be coordinated by a main controller 62. The main controller 62, like the individual controllers 50, may be a microcontroller, a microprocessor, an ASIC, an FPGA, or any other device that can perform the functions ascribed to it here, and it would typically have more capacity or more functionality than an individual controller 50, at least in particular ways.

Although the battery management system 10 has a number of functions in the health and performance of the battery pack 12, the remainder of this description will focus on particular methods for cell balancing. These methods would typically be implemented as sets of machine-readable instructions on machine-readable medium that, when executed by a machine, cause that machine to perform certain tasks. In this particular case, the machine in question would usually be a controller 50, a master controller 62, or some other device performing the functions of monitoring and managing a battery pack 12 or battery packs 12. The sets of machine-readable instructions would typically be implemented as part of the embedded firmware of a controller 50, a master controller 62, or another such device, although they could be implemented as more general software that runs on devices like these. Such sets of machine-readable instructions could also be implemented in other non-transitory, machine-readable media, like flash memory, hard disk drives, solid-state drives and the like. In some cases, if battery management systems 10 are being mass-produced, the machine-readable instructions could be provided on a master medium that is used to install the machine-readable instructions on a number of devices during manufacturing.

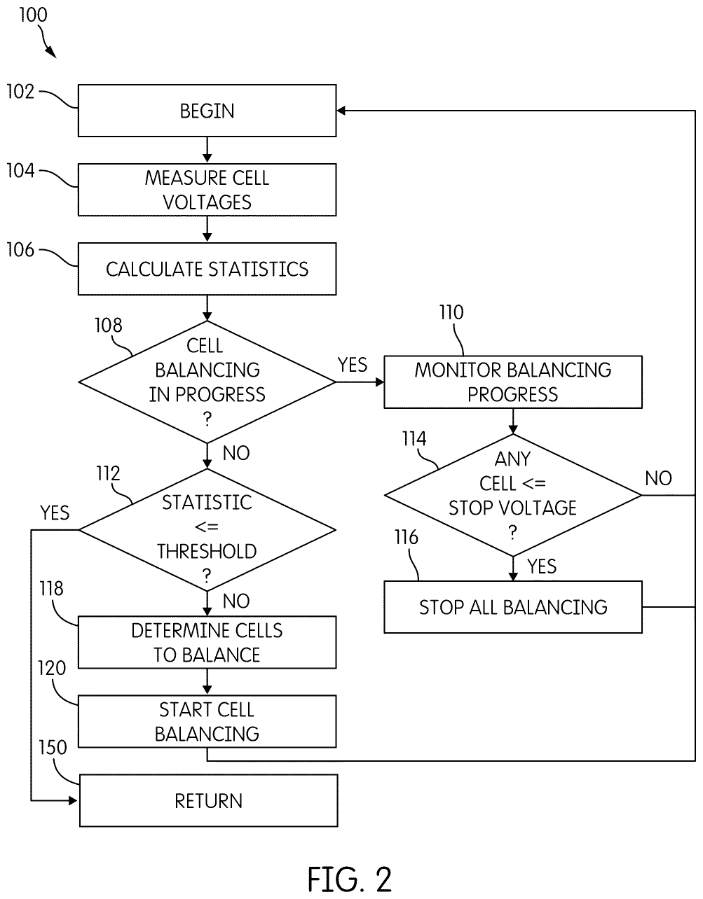

FIG. 2 is a flow diagram of a method for cell balancing, generally indicated at 100, according to one embodiment of the invention. Generally speaking, when executed on a device like the controller 50 or master controller 62, method 100 selectively discharges cells 14 until the voltages of all cells 14 are the same to within a predefined tolerance. The following description of method 100 will use the battery management system 10 and battery pack 12 of FIG. 1 as an exemplary system that might use such a method. However, method 100 has broad application and may be used with many different types of battery management systems and battery packs.

Method 100 is but one of many methods or processes that may be executed on a controller 50 or master controller 62. In general, method 100 would be executed whenever cell balancing is needed. To ensure that the battery pack 12 is always able to discharge the greatest amount of power possible, method 100 may be run essentially continuously in many operating states, particularly when the battery pack 12 is not discharging. However, in some particular operating states, methods like method 100 may not be executed, e.g., while the battery pack 12 is discharging, or when the cells 14 of the battery pack are so drained that nothing productive can be achieved by attempting to balance them.

The question of whether and when methods like method 100 are used may also depend on the voltage-current characteristics of the cells 14. If the cells 14 have a discharge curve (i.e., a voltage-current curve) that is nearly flat over most of the operating range of the cell, i.e., the cells 14 can discharge current at essentially the same voltage for most states of charge, then a balancing method like method 100 may be most useful when the cells 14 are near full charge, and such methods may not be used as frequently in other states of charge. By contrast, if the discharge curve is steep, i.e., the discharge voltage is strongly dependent on the state of charge of a cell 14 and varies greatly with the state of charge, then a method like method 100 may be used more frequently and with the cells in a greater variety of charge-states. In practice, any controller 50 would be programmed with at least some indication of the battery type and chemistry it serves, and that indication could be considered in determining when to execute a method like method 100.

In some cases, prior to the execution of method 100, some other process will determine that it is both necessary and appropriate to execute a method like method 100. However, in many cases, a controller 50 may simply execute method 100, e.g., at a regular interval, and method 100 itself will terminate and return if it determines that the battery cells 14 are not in a suitable state for cell balancing, or if cell balance has been achieved. The conditions under which method 100 terminates will be described below in more detail.

Method 100 begins at task 102 and continues with task 104, in which the voltages of the cells 14 are measured. In many implementations, task 104 will be performed at a regular interval, often at least several times per second, and the results continuously placed into some form of readable memory. The interval or frequency with which task 104 is performed will depend on several factors, including the rate at which stable measurements of voltage can actually be obtained and the limitations of the controller 50. As one example, if the controller 50 is a BQ76490 battery monitor (Texas Instruments, Dallas, Texas, United States), the voltages of the cells 14 may be measured every 250 ms (i.e., at a rate of 4 Hz).

If the voltages of the cells 14 are measured continuously or nearly continuously, that means that the measurement tasks are essentially decoupled from the battery balancing tasks performed in the remainder of method 100—i.e., recent cell voltage data is available regardless of the status of method 100. For these reasons, in at least some cases, the true action of task 104 may be reading or retrieving a set of cell voltages that have been recently measured and stored for use, rather than measuring them per se. Method 100 continues with task 106.

In task 106, one or more statistics describing the cell voltages are calculated. These statistics attempt to characterize the voltages of at least a significant number of the cells 14 and, in at least some embodiments, may focus on the central tendency and variability of the cell voltages. For example, in task 106, the controller 50 may calculate a mean and a standard deviation for the cell voltages, and it may also choose to flag the cells 14 with the maximum voltage and the minimum voltage. Other variability statistics, like the range of the cell voltages, may also be used. Other central tendency statistics that may be used include the mode of the cell voltages. Other types of statistics may be used in other embodiments. Method 100 continues with task 108.

Task 108 is a decision task. In task 108, the controller 50 determines whether or not there is already a cell balancing process in progress. If so (task 108:YES), method 100 continues with task 110. If not (task 108:NO), method 100 continues with task 112.

In task 110, it has been determined that there is some cell balancing process in progress. Thus, method 100 monitors that progress, and method 100 continues with task 114, a decision task. In task 114, if any cell has a voltage less than or equal to a stop voltage (task 114:YES), then method 100 continues with task 116 and the cell balancing process is stopped before control of method 100 returns to task 102. A “stop voltage,” as that term is used here, refers to a cell voltage indicating that balancing should not continue. A stop voltage may indicate, for example, that the voltage of a particular cell has fallen below a threshold level. For example, if the mean cell voltage is calculated in task 106, the mean cell voltage may be used as a stop voltage in task 114. That is, in task 114, if any cell has a voltage less than or equal to the mean cell voltage, cell balancing is stopped.

When task 112 is executed, it has been determined that there is no existing cell balancing process in progress (i.e., task 108:NO). Task 112 is itself a decision task. If an appropriate statistic calculated in task 106 is less than or equal to a threshold value (task 112:YES), the controller concludes that cell balancing has been successful and terminates/returns at task 150. For example, if the standard deviation is calculated in task 106 and is determined to be less than or equal to the threshold value in task 112, then the controller 50 would conclude that cell balancing has been successful (task 112:YES). The threshold would typically be predetermined based on the maximum amount of imbalance that can be tolerated in the particular application. On the other hand, if in task 112, the statistic is greater than the threshold (task 112:NO), the controller 50 concludes that more balancing is to be done, and method 100 continues with task 118.

In task 118, the controller 50 determines which cells 14 require balancing. The controller 50, master controller 62, or some other associated device may be programmed with rules as to which cells 14 to prioritize, which cells 14 can be balanced simultaneously, etc. For example, limitations in the switching elements may impose some limitations, e.g., that no two adjacent cells can be balanced simultaneously. In general, and as an example, the controller 50 may prioritize the cell or cells 14 with the maximum voltage, followed by the cell or cells 14 with the next-highest voltages, followed by any cell 14 with a voltage greater than the mean cell voltage. Other rules may be used in other embodiments. Once the cells that are to be balanced in this iteration of method 100 are determined, method 100 continues with task 120 and cell balancing begins, i.e., the cells 14 in question are caused to discharge power. After task 120, control of method 100 returns to task 102 and continues from that point.

Method 100 and other methods according to embodiments of the invention may have a number of advantages. For example, other, more conventional balancing algorithms generally do not consider the state of charge of all of the cells, or the variability in the various states of charge, when choosing a voltage setpoint for cell balancing. Instead, these algorithms may simply attempt to balance the cells to the lowest measured cell voltage. This is inefficient and can waste power. By contrast, method 10 may consume less power and achieve balance somewhat more quickly than other algorithms. Method 100 may also be more efficient or otherwise better suited for battery packs containing large numbers of cells.

As may be clear from the above description, method 100 may be used in a variety of battery management systems, serving battery packs of various sizes and in various applications. One particular system in which method 100 may be useful is an uninterruptible power supply (UPS). A UPS uses battery packs to provide power to electronic equipment if a main power supply fails or is otherwise unavailable and typically does so in such a way that the transition between main power and reserve power is seamless. U.S. Pat. No. 11,489,362, the contents of which are incorporated by reference herein in their entirety, describes one example of a UPS with which method 100 may be used. The UPS of this patent converts all incoming power to direct current and has a power bus, to which a battery pack or packs are coupled. This arrangement means that there is no need to physically switch between main power and reserve power; the bus is always powered, and it automatically draws power from whichever source or sources are available. The battery pack or packs in this UPS can also be used to temporarily provide supplemental power if the load on the UPS demands more power than can be supplied by the main power source.

However, any system that uses battery packs for power could potentially benefit from a method like method 100. This includes electric cars, solar power systems, consumer electronics, and cordless tools, to name a few. Embodiments of the invention include systems and devices like these, having battery management systems that are configured to perform methods like method 100.

The amount of time it takes to achieve balance with a method like method 100 will depend on the nature of the battery pack 12 and the equipment and manner in which it is used. As one example, the battery packs of a UPS are relatively rarely discharged and spend most of their time at or near full charge. Thus, in a UPS, method 100 may be run so that the cells 14 are discharged slowly when balancing is necessary, taking hours before any change in the cell voltages is readily apparent, and days before the cells 14 in the battery pack 12 are fully balanced. Slow balancing may also reduce any potential impact on the overall condition of the cells 14. However, in other applications, methods like method 100 may be run such that cell balancing happens much more quickly.

### Example

A numerical simulation was created to verify the basic operation of a method according to an embodiment of the invention. For this example, three simulated battery packs were created, each assumed to be comprised of 14 lithium iron phosphate cells, type 26650. Each battery pack was assumed to be managed by a BQ76490 battery monitor.

To begin the simulation, each simulated battery cell was randomly assigned a voltage between 2600 mV and 3200 mV. Method 100 of FIG. 1 was then executed on the simulated battery packs and simulated cells. Specifically, the voltage data for each cell was read, and voltage metrics were calculated. For purposes of the simulation, the metrics included the minimum cell voltage in each battery pack, the maximum cell voltage in each battery pack, the average cell voltage in each battery pack, and the standard deviation of cell voltage in each battery pack. If balancing was needed (i.e., in this case, if the standard deviation was greater than a threshold of 10 mV), the current average voltage was saved as a target average. Any low-voltage cells (i.e., cells in which the cell voltage was less than the average voltage minus the standard deviation) were flagged.

Cells were then selected for balancing (i.e., controlled discharge) based on a set of priority rules. The cells with the maximum voltage in each battery pack were assigned the highest priority for balancing. Any cells with a cell voltage greater than the average voltage plus the standard deviation were given next-priority. Any cells with a voltage greater than the average voltage were given the last priority for balancing. In choosing which cells to balance, the locations of the cells in the battery pack were mapped and the balancing restrictions of the BQ76490 battery monitor were obeyed. Specifically, cells that would not be permitted to be balanced simultaneously in practice were not balanced simultaneously during the simulation. (These kinds of restrictions are typically due to the arrangement of transistors in the battery management system.)

The simulation was divided into time intervals of arbitrary duration. In each time interval, after steps were taken to measure battery cell voltages, calculate descriptive metrics or statistics of charge, and prioritize cells for balancing, the simulation assigned new voltages to cells that were charged or balanced in that time interval.

For purposes of the simulation, it was assumed that any given cell was either charging or idle when selected for balancing. For cells that were charging, it was assumed that balancing was still possible, but that cells that were both balancing and charging would charge at a slower rate. By this rationale, 1 mV was added to the voltage of each cell that was both charging and balancing. It was also assumed that charging cells that were not balancing would charge normally, and 1% change in the state of charge was assumed and added to the voltages of those cells. Since the relationship between the state of charge and the cell voltage is not necessarily linear, a lookup table was constructed based on manufacturer data for a 26650 lithium ion phosphate cell to determine the voltage of the cell for any given state of charge. That lookup table is presented below as Table 1. If a cell was idle (i.e., not charging) and was balancing during the time interval, 2 mV was subtracted from its voltage for that time interval. Cells that were not balancing or charging in a particular time interval were not assigned a voltage change in that time interval.

TABLE 1
Lookup table for battery cell voltage given
a state of charge for LiFe(PO₄) cell.

| SOC | Voltage |
|---|---|
| (%) | (mV) |
| 0 | 2672 |
| 1 | 2734 |
| 2 | 2797 |
| 3 | 2859 |
| 4 | 2922 |
| 5 | 2984 |
| 6 | 3046 |
| 7 | 3109 |
| 8 | 3171 |
| 9 | 3234 |
| 10 | 3296 |
| 11 | 3300 |
| 12 | 3305 |
| 13 | 3309 |
| 14 | 3313 |
| 15 | 3318 |
| 16 | 3322 |
| 17 | 3326 |
| 18 | 3330 |
| 19 | 3335 |
| 20 | 3339 |
| 21 | 3343 |
| 22 | 3347 |
| 23 | 3351 |
| 24 | 3355 |
| 25 | 3360 |
| 26 | 3364 |
| 27 | 3368 |
| 28 | 3372 |
| 29 | 3376 |
| 30 | 3380 |
| 31 | 3381 |
| 32 | 3382 |
| 33 | 3383 |
| 34 | 3384 |
| 35 | 3385 |
| 36 | 3386 |
| 37 | 3387 |
| 38 | 3388 |
| 39 | 3389 |
| 40 | 3390 |
| 41 | 3391 |
| 42 | 3392 |
| 43 | 3394 |
| 44 | 3395 |
| 45 | 3396 |
| 46 | 3397 |
| 47 | 3398 |
| 48 | 3400 |
| 49 | 3401 |
| 50 | 3402 |
| 51 | 3403 |
| 52 | 3405 |
| 53 | 3406 |
| 54 | 3407 |
| 55 | 3409 |
| 56 | 3410 |
| 57 | 3411 |
| 58 | 3412 |
| 59 | 3414 |
| 60 | 3415 |
| 61 | 3416 |
| 62 | 3418 |
| 63 | 3419 |
| 64 | 3421 |
| 65 | 3422 |
| 66 | 3423 |
| 67 | 3425 |
| 68 | 3426 |
| 69 | 3428 |
| 70 | 3429 |
| 71 | 3430 |
| 72 | 3431 |
| 73 | 3432 |
| 74 | 3433 |
| 75 | 3435 |
| 76 | 3436 |
| 77 | 3437 |
| 78 | 3438 |
| 79 | 3439 |
| 80 | 3440 |
| 81 | 3443 |
| 82 | 3446 |
| 83 | 3448 |
| 84 | 3451 |
| 85 | 3454 |
| 86 | 3457 |
| 87 | 3460 |
| 88 | 3462 |
| 89 | 3465 |
| 90 | 3468 |
| 91 | 3486 |
| 92 | 3504 |
| 93 | 3523 |
| 94 | 3541 |
| 95 | 3559 |
| 96 | 3577 |
| 97 | 3595 |
| 98 | 3614 |
| 99 | 3632 |
| 100 | 3650 |

The functions used to implement the balancing method in the simulation were the same functions that would be used to implement “live” cell balancing methods. Thus, the conditions for terminating cell balancing operations were the same in the simulation as they would be in practice. More specifically, cell balancing continued until there was a load on the cells requiring discharge; in the cell-charging state, any cell voltage became less than the target average; in the idle state, any cell that was balancing had a voltage less than the target average; when charging, any cell reached fully charged; when charging, any low-voltage cell reached the target average; or when the calculated standard deviation became less than a predefined threshold.

The simulation was run twice, once assuming a cell-charging state, and once assuming a cell-idle state. In both cases, the cell balancing method was successful in balancing the cells.

While the invention has been described with respect to certain embodiments, the description is intended to be exemplary, rather than limiting. Modifications and changes may be made within the scope of the invention, which is defined by the appended claims.

What is claimed is:

1. A method, comprising:
calculating at least a central tendency statistic and a variability statistic describing a set of battery cell voltages for a set of battery cells; and
while the variability statistic is greater than a predefined threshold and each of the set of battery cell voltages is greater than a stop voltage, draining ones or groups of the set of battery cells according to a predefined set of priority rules until the variability statistic is less than or equal to the predefined threshold or any one of the set of battery cells has a cell voltage less than or equal to a stop voltage.

2. The method of claim 1, wherein said calculating and said draining are performed automatically by a battery management system associated with a battery pack containing the set of battery cells.

3. The method of claim 2, further comprising measuring the set of battery cell voltages repeatedly and automatically at a defined interval, independently of said calculating and said draining.

4. The method of claim 1, wherein the central tendency statistic comprises a mean of the set of battery cell voltages, and the variability statistic comprises a standard deviation of the set of battery cell voltages.

5. The method of claim 4, wherein the stop voltage comprises the mean of the set of battery cell voltages.

6. A battery management system, comprising at least one controller adapted to:
measure a set of battery cell voltages from a battery pack;
calculate at least a central tendency statistic and a variability statistic describing the set of battery cell voltages; and
while the variability statistic is greater than a predefined threshold and each of the set of battery cell voltages is greater than a stop voltage, drain ones or groups of the set of battery cells according to a predefined set of priority rules until the variability statistic is less than or equal to the predefined threshold or any one of the set of battery cells has a cell voltage less than or equal to a stop voltage.

7. The battery management system of claim 6, wherein said calculating and said draining are performed automatically by a battery management system associated with a battery pack containing the set of battery cells.

8. The battery management system of claim 6, wherein the central tendency statistic comprises a mean of the set of battery cell voltages, and the variability statistic comprises a standard deviation of the set of battery cell voltages.

9. The battery management system of claim 8, wherein the stop voltage comprises the mean of the set of battery cell voltages.

10. The battery management system of claim 6, wherein the controller measures the set of battery cell voltages at a regular, independent interval.

11. A system, comprising:
a battery pack including a set of battery cells, the set of battery cells connected together and adapted to produce a collective power, ones of the set of battery cells having power connections to receive and to discharge power individually or in groups, and a set of monitoring terminals;
one or more switching elements connected to the power connections so as to direct power input to and output from the set of battery cells;
a controller connected to the set of monitoring terminals and to the one or more switching elements, the controller adapted to
calculate at least a central tendency statistic and a variability statistic describing a set of battery cell voltages for the set of battery cells, and
while the variability statistic is greater than a predefined threshold and each of the set of battery cell voltages is greater than a stop voltage, drain ones or groups of the set of battery cells according to a predefined set of priority rules until the variability statistic is less than or equal to the predefined threshold or any one of the set of battery cells has a cell voltage less than or equal to a stop voltage.

12. The system of claim 11, wherein the controller measures the set of battery cell voltages repeatedly and automatically at a defined interval, independently of said calculating and said draining.

13. The system of claim 11, wherein the central tendency statistic comprises a mean of the set of battery cell voltages, and the variability statistic comprises a standard deviation of the set of battery cell voltages.

14. The system of claim 13, wherein the stop voltage comprises the mean of the set of battery cell voltages.
